(19) United States
(12) Patent Application Publication
(10) Pub. No.: US 2015/0035067 A1
(43) Pub. Date: Feb. 5, 2015

(54) LOW RDSON DEVICE AND METHOD OF MANUFACTURING THE SAME

(71) Applicant: GLOBALFOUNDRIES Singapore Pte. Ltd., Singapore (SG)

(72) Inventors: Guowei ZHANG, Singapore (SG); Surya Kris AMETHYSTNA, Singapore (SG)

(21) Appl. No.: 14/447,629

(22) Filed: Jul. 31, 2014

Related U.S. Application Data
(60) Provisional application No. 61/862,508, filed on Aug. 5, 2013.

(51) Int. Cl. H01L 29/78; H01L 21/265; H01L 27/088; H01L 29/66

(52) U.S. Cl. CPC H01L 29/7835; H01L 29/7836; H01L 29/66492; H01L 21/26513; H01L 27/088
USPC 257/368; 257/408; 438/286

(57) ABSTRACT

A device and method of making thereof are disclosed. The device includes a substrate having a device region for a switch transistor. The device includes a switch transistor having a gate disposed on the substrate in the device region and first and second heavily doped regions disposed adjacent to the gate. The first heavily doped region serves as a source region of the switch transistor and the second heavily doped region serves as a drain region of the switch transistor. The drain region includes a lightly doped diffusion (LDD) region adjacent thereto and the source region is devoid of a LDD region.

### CROSS-REFERENCE TO RELATED APPLICATION

This application claims the priority benefit of U.S. Provisional Application Ser. No. 61/862,508, filed on Aug. 5, 2013, which is herein incorporated by reference in its entirety.

### BACKGROUND

Power management circuits are widely employed in portable electronic devices including mobile phones, tablets, etc. Switched-mode power supply (SMPS) is commonly used as the power management circuit in these portable electronic devices due to its high power conversion efficiency, low power dissipation and high power density. A general SMPS circuit typically includes components such as metal-oxide-semiconductor field-effect-transistors (MOSFETs) and/or diodes, an inductor and an output capacitor. The MOSFET acts as the switch in the SMPS circuit and is interfaced to a controller. The controller applies a pulse-width-modulated (PWM) square—wave signal to the MOSFET's gate, thereby switching the device on and off. To offer consumer extended run time while using their favorite portable electronic products, there is always a need to increase the switching speed and reduce power loss for the SMPS circuit employed in these devices.

From the foregoing discussion, there is a desire to provide high speed and power efficient devices and method of making thereof.

### SUMMARY

Embodiments generally relate to semiconductor devices or integrated circuits (ICs) and methods for forming the devices. Some embodiments relate to a MOSFET with low drain-to-source on resistance (R_{DSon}). The low R_{DSon} MOSFET can be employed as a switch in a switched-mode power supply (SMPS) circuit. In one embodiment, a device is disclosed. The device includes a substrate having a device region for a switch transistor. The device includes a switch transistor having a gate disposed on the substrate in the device region and first and second heavily doped regions disposed adjacent to the gate. The first heavily doped region serves as a source region of the switch transistor and the second heavily doped region serves as a drain region of the switch transistor. The drain region includes a lightly doped diffusion (LDD) region adjacent thereto and the source region is devoid of a LDD region.

In another embodiment, a method of forming a device is presented. The method includes providing a substrate having a first device region for a switch transistor. A switch transistor having a gate is formed on the substrate in the first device region. First and second heavily doped regions are formed adjacent to the gate. The first heavily doped region serves as a source region of the switch transistor and the second heavily doped region serves as a drain region of the switch transistor. The drain region includes a lightly doped diffusion (LDD) region adjacent thereto and the source region is devoid of a LDD region.

In yet another embodiment, a method of forming a device is presented. The method includes providing a substrate having at least a first device region for a first transistor and a second device region for a second transistor. A first gate having first and second sidewalls on the first device region and a second gate having first and second sidewalls on the second device region are formed. The gates include sidewall spacers on their sidewalls. Heavily doped regions are formed adjacent to the gates. Inner edges of the heavily doped regions are aligned with about inner edges of the sidewall spacers of the gates. The heavily doped regions serve as source/drain (S/D) regions of the gates. The source region of the first transistor does not include lightly doped diffusion (LDD) region.

These and other advantages and features of the embodiments herein disclosed, will become apparent through reference to the following description and the accompanying drawings. Furthermore, it is to be understood that the features of the various embodiments described herein are not mutually exclusive and can exist in various combinations and permutations.

### BRIEF DESCRIPTION OF THE DRAWINGS

In the drawings, like reference characters generally refer to the same parts throughout the different views. Also, the drawings are not necessarily to scale, emphasis instead generally being placed upon illustrating the principles of the invention. In the following description, various embodiments of the present invention are described with reference to the following drawings, in which:

FIG. 1 shows a cross-sectional view of an embodiment of a device;

FIGS. 2a-2f show cross-sectional views of an embodiment of a process for forming a device; and

FIGS. 3a-3c show graphs charting exemplary performance data of the switch transistor in accordance with the embodiment as described in FIG. 1 and a conventional switch transistor.

### DESCRIPTION

Embodiments generally relate to semiconductor devices or integrated circuits (ICs). More particularly, some embodiments relate to a MOSFET with low drain-to-source on resistance (R_{DSon}). The low R_{DSon} MOSFET can be employed as a switch in a switched-mode power supply (SMPS) circuit. The SMPS circuit can be easily incorporated into or used with, for example, consumer electronic products, and particularly portable consumer products including mobile phones, tablets, etc. The low R_{DSon} MOSFET can be formed together with other input/output (I/O) devices on the same substrate without incurring extra processing cost.

A SMPS circuit which employs the low R_{DSon} MOSFET according to the present disclosure offers a number of advantages compared to conventional power management circuits. For instance, the switching speed is improved and power loss during switching cycles is reduced.

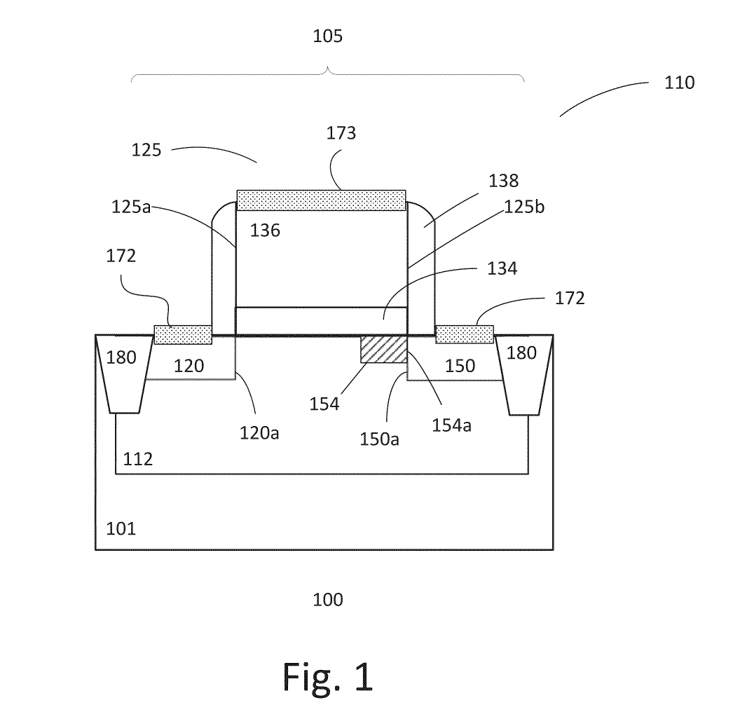

FIG. 1 shows a cross-sectional view of a portion of an embodiment of a device 100. The device, for example, is an IC. Other types of devices may also be useful. As shown, the device includes a substrate 101. The substrate, for example, is a silicon substrate. Other types of substrates, such as silicon germanium, germanium, gallium arsenide, or crystal-on-insulator (COI) such as silicon-on-insulator (SOI), are also useful. The substrate may be a doped substrate. For example, the substrate can be lightly doped with p-type dopants. Providing a substrate with other types of dopants or dopant concentrations, as well as an undoped substrate, may also be useful.

The device may include doped regions having different dopant concentrations. For example, the device may include heavily doped (x⁺), intermediately doped (x) and lightly doped (x⁻) regions, where x is the polarity type which can be a p-type or n-type. A lightly doped region may have a dopant concentration of about 1E11-1E13/cm², and an intermediately doped region may have a dopant concentration of about 1E13-1E15/cm², and a heavily doped region may have a dopant concentration of about 1E15-1E17/cm², providing other dopant concentrations for the different types of doped regions may also be useful. For example, the ranges may be varied, depending on the technology node. P-type dopants may include boron (B), aluminum (Al), indium (In) or a combination thereof, while n-type dopants may include phosphorous (P), arsenic (As), antimony (Sb) or a combination thereof.

The substrate includes a device region 105 for a transistor 110. The transistor, in one embodiment, is a switch transistor. The switch transistor, for example, is used as a main switch transistor for a SMPS circuit. Although one device region is shown, it is understood that the substrate may also include regions for other types of circuitry, depending on the type of device or IC. For example, the substrate may also include regions (not shown) for high voltage (HV), intermediate voltage (IV) input/output (I/O) devices and/or low voltage (LV) logic devices. Providing other device regions may also be useful.

Isolation regions may be provided for isolating or separating different regions of the substrate. In one embodiment, the device region 105 is isolated from other regions (not shown) by isolation regions 180. For example, an isolation region surrounds a device region. The isolation regions, for example, are shallow trench isolation (STI) regions. Other types of isolation regions may also be employed. For example, the isolation regions may be deep trench isolation (DTI) regions. The STI regions, for example, extend to a depth of about 2000-5000 Å. Providing isolation regions which extend to other depths may also be useful.

A device well 112 may be disposed in the device region 105. The device well is disposed within the isolation region. A depth of the device well may be about 0.5-5 μm. Other suitable depths for the device well may also be useful. In one embodiment, the device well is doped with second polarity type dopants. For example, the device well is doped with p-type dopants. Alternatively, the second polarity type dopants may be n-type. The device well serves as a body of the transistor. For example, the device well in the device region serves as a body of the transistor 110. The dopant concentration of the device well may be light to intermediate. For example, the dopant concentration of the device well may be about 5E12-5E13/cm². Other suitable dopant concentration for the device well may also be useful.

The transistor 110 includes a gate 125 on the surface of the substrate. The gate, for example, includes a gate electrode 136 over a gate dielectric 134. The gate electrode, for example, may be polysilicon. The gate electrode may be about 1000-5000 Å thick. Other suitable types of gate electrodes as well as thicknesses may also be useful. As for the gate dielectric, it may be formed of silicon oxide. The thickness of the gate dielectric may be, for example, about 50-200 Å. Other suitable types of gate dielectrics or thicknesses may also be useful.

The gate may be a gate conductor which forms gates of multiple transistors. For example, the gate conductor may traverse a plurality of device regions separated by isolation regions. The pluralities of transistors have a common gate formed by the gate conductor. Other configurations of gate conductors may also be useful.

Dielectric sidewall spacers 138 are disposed on sidewalls of the gate 125. The sidewall spacers for example, may be silicon oxide. Other suitable types of dielectric materials or combination of materials may be used for the spacers. For example, the spacers may be silicon nitride or multiple layers of dielectric materials, such as silicon oxide and silicon nitride.

The transistor 110 includes first and second first type doped regions 120 and 150 disposed in the substrate adjacent to the sides of the gate. For example, the doped region 150 is disposed adjacent to about an inner edge of the dielectric sidewall spacer 138 of the gate 125 and the other doped region 120 is disposed adjacent to about an inner edge of the other dielectric sidewall spacer 138 of the gate 125. The first type doped regions, for example, extend from the isolation regions 180 to about the sides of the gate 125. In one embodiment, inner edges of the first type doped regions 120a and 150a are aligned with about inner edges of the dielectric sidewall spacers of the gate. The first type doped regions, in one embodiment, are heavily doped with first polarity type dopants for a first type transistor. For example, the first type doped regions are heavily doped n-type (n⁺) regions of a n-type transistor. Providing heavily doped p-type (p⁺) regions may also be useful for a p-type transistor. The heavily doped regions, for example, have a dopant concentration of about 1E15-1E17/cm². Other suitable dopant concentrations for the first type doped regions may also be useful. The depth of the doped regions may be about 0.1-0.4 μm. Providing doped regions having other depths may also be useful. Additionally, it is not necessary that the first type doped regions 120 and 150 have the same depth. In one embodiment, the first doped region 120 serves as the source region of the transistor while the second doped region 150 serves as the drain region of the transistor.

In one embodiment, the transistor 110 includes a second type doped region 154. The second type doped region 154, in one embodiment, is a lightly doped diffusion or lightly doped drain (LDD) region. For example, the LDD region is disposed adjacent to the drain region 150. In one embodiment, the LDD region extends from the drain region 150 to underlap the gate 125. The source region 120, in one embodiment, is devoid of a LDD region. For example, the absence of a LDD region adjacent to the source region forms a non-symmetrical or asymmetrical transistor.

As shown in FIG. 1, the gate includes first and second sidewalls 125a and 125b. The outer edge 154a of the LDD region, as shown, is aligned with about the second sidewall 125b of the gate. The LDD region should underlap the gate sufficiently to extend the drain electrical field so that it can sustain high bias voltage with low electrical field crowding at the drain. This can improve its hot carrier injection reliability. The underlap portion may be, for example, about 0.1-0.3 μm. Providing an underlap portion which underlaps the gate by other amounts may also be useful. The LDD region, in one embodiment, is lightly doped with first polarity type dopants for a first type transistor. For example, the LDD region is a lightly doped n-type (n⁻) region for a n-type transistor. Providing a lightly doped p-type (p⁻) region may also be useful for a p-type transistor. The LDD region, for example, has a dopant concentration of about 1E13-1E14/cm². Other suitable dopant concentrations for the LDD region 154 may also be useful. The depth of the LDD region may be about 0.05-0.3 μm. Providing a LDD region having other suitable depths may also be useful.

The region of the substrate under the gate and between the source and drain regions correspond to a channel of the transistor. As described, the transistor 110 is an asymmetrical transistor of which the LDD region is disposed adjacent to the drain region and the source region is devoid of a LDD region. In one embodiment, the effective channel length of the transistor 110 is increased relatively to symmetrical transistor where LDD regions are formed adjacent to both the source and drain regions. In one embodiment, the effective channel length (L_{C}) of the transistor 110 is about 0.1-0.3 μm. Providing other suitable effective channel length dimensions may also be useful, for example, depending on design requirements.

In some embodiments, a dielectric etch stop layer (not shown) is formed over the transistors. The etch stop layer, for example, is a silicon nitride etch stop layer. Other types of etch stop layers may also be useful. The etch stop layer should have a material which can be selectively removed from a dielectric layer thereover. The etch stop layer facilitates in forming contact plugs to contact regions of the transistor, such as the gate electrode and doped regions. In some embodiments, the etch stop layer may also serve as a stress layer for applying a stress on the channel of the transistor to improve performance.

Metal silicide contacts 172 and 173 may be formed on the S/D regions and on the gate electrode. The metal silicide contacts, for example, may be nickel-based contacts. Other types of metal silicide contacts may also be useful. For example, the metal silicide contact may be cobalt silicide (CoSi). The silicide contacts may have a thickness of about 50-300 Å. Other suitable thicknesses may also be useful. The metal silicide contacts may be employed to reduce contact resistance and facilitate contact to the back-end-of-line (BEOL) metal interconnects. For example, an interlevel dielectric (ILD) layer (not shown) may be provided over the transistor. Via contacts, such as tungsten contacts, may be formed in the ILD layer coupling the contact regions of the transistor to metal lines (not shown) disposed in metal layers of the device.

The transistor 110 as described above offers several advantages. As described, the LDD region is formed adjacent to the drain region and the source region is devoid of a LDD region. This allows for shrinking the size of the transistor so that the R_{DSon} can be lowered without affecting the drain electric field distribution. In addition, without the LDD region adjacent to the source region, gate overlap capacitance in the source region is reduced, thereby improving the switching speed of the switch transistor.

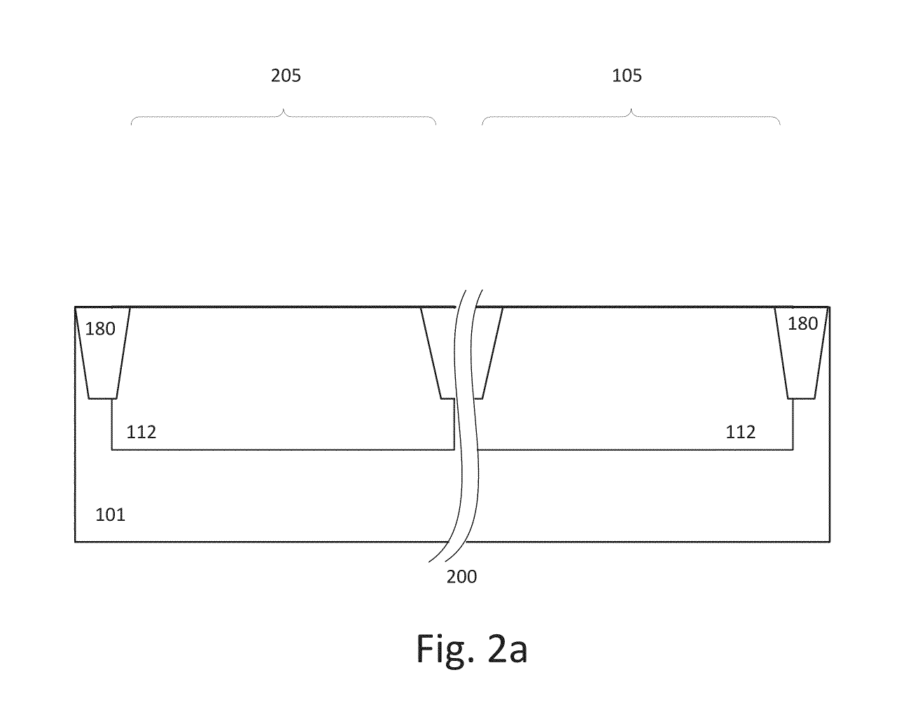

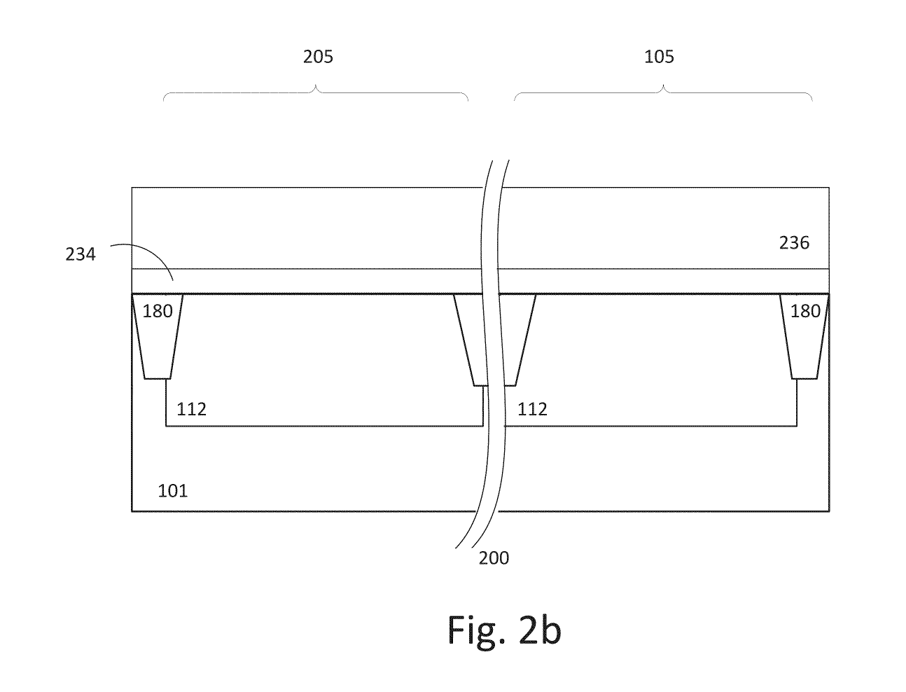

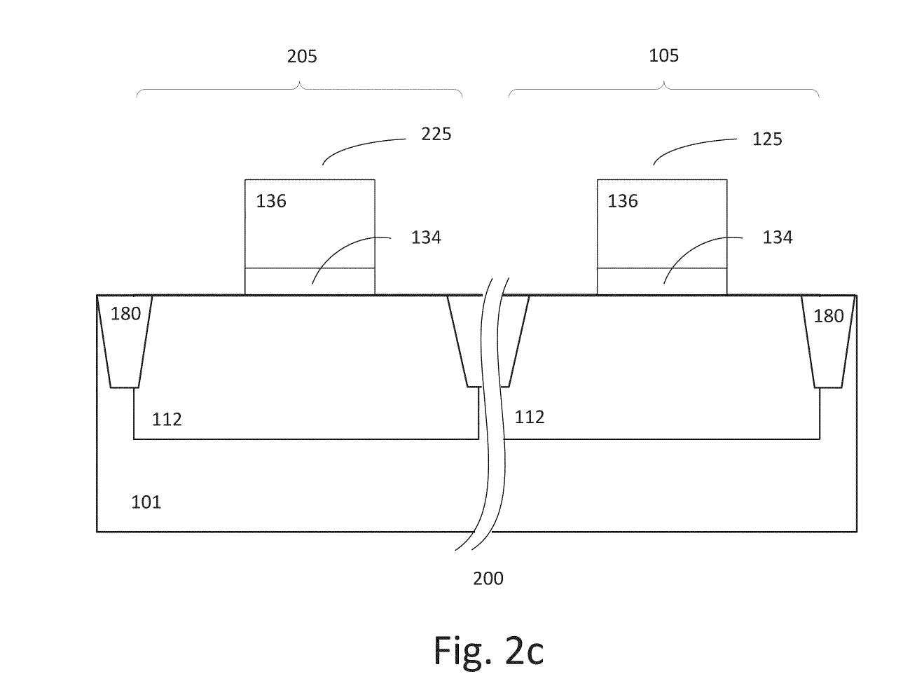

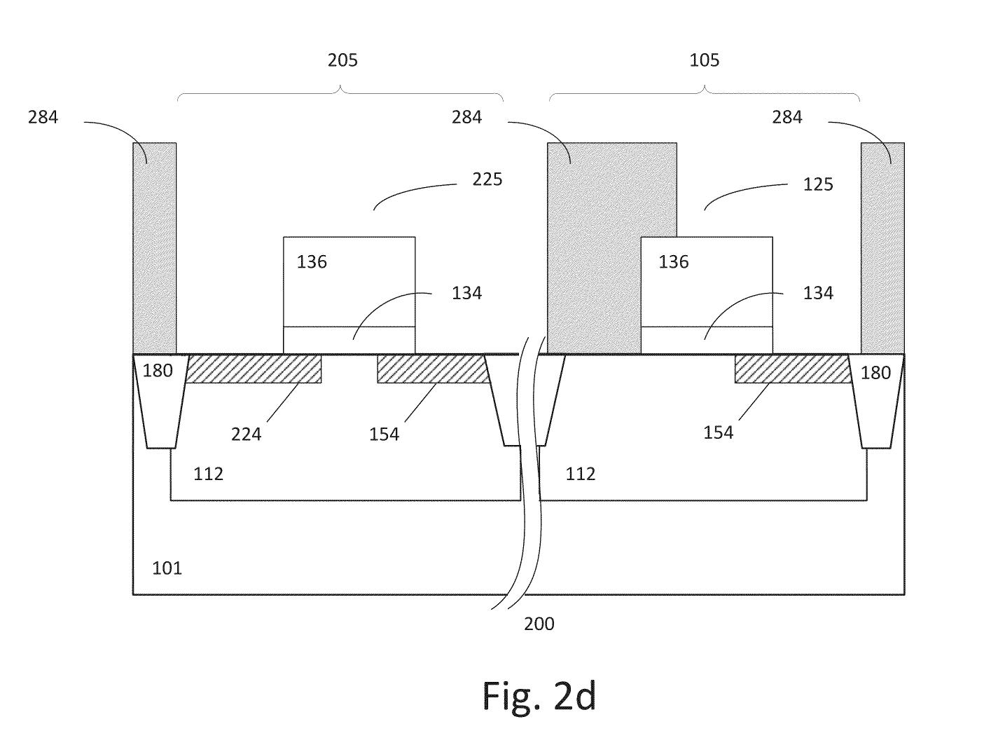

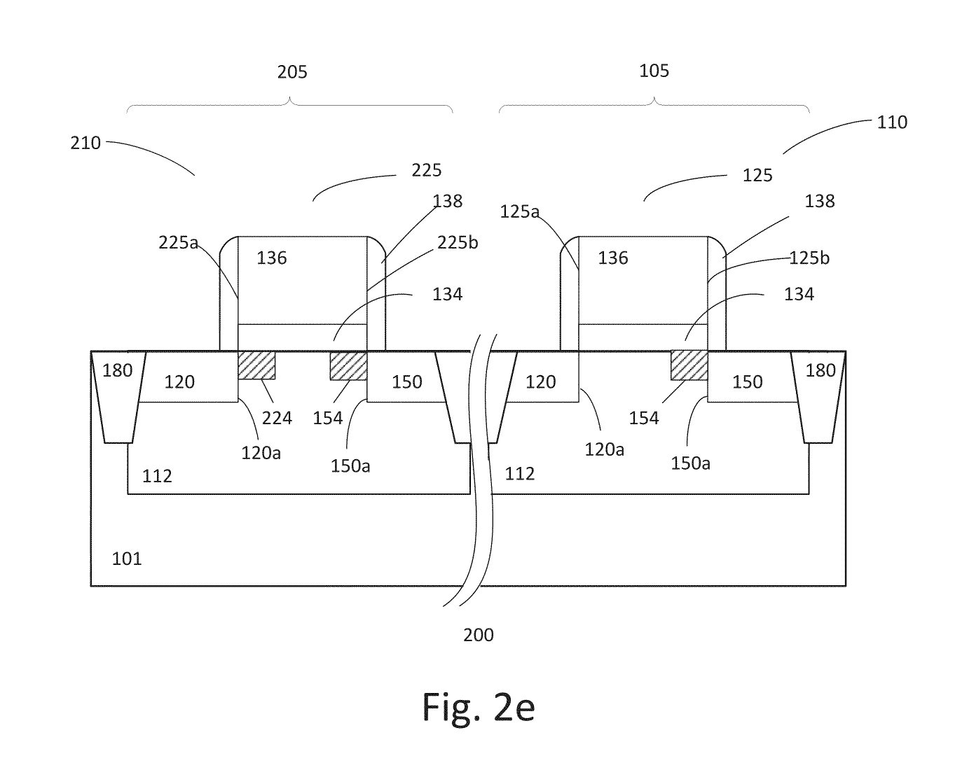

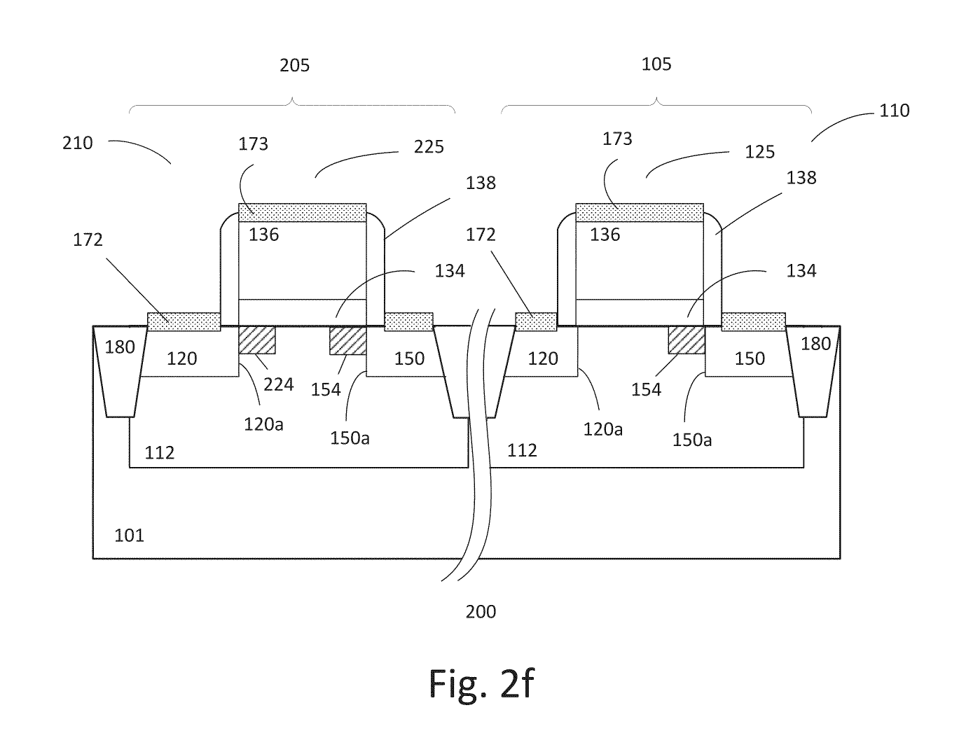

FIGS. 2a-2f show cross-sectional views of an embodiment of a process 200 for forming a device. Referring to FIG. 2a, a substrate 101 is provided. The substrate, in one embodiment, is a silicon substrate. The substrate may be a doped substrate, such as a p⁻ substrate. Other suitable types of substrates, such as germanium-based, gallium arsenide, COI such as SOI, or sapphire, may also be useful. The substrate may be doped with other types of dopants or dopant.

The substrate 101 includes first and second device regions 105 and 205. In one embodiment, the first device region 105 is for a switch transistor and the second device region 205 is for an input/output (I/O) transistor. In one embodiment, the second device region 205 is for medium voltage I/O transistor. For example, the second device region is suitable for 3.3-8 V I/O transistors. Other voltage ranges may also be useful. The substrate may also include regions (not shown) for other types of circuitry, depending on the type of device or IC. For example, the substrate may also include regions (not shown) for high voltage devices, low voltage (LV) logic devices and/or array region for memory devices. Providing other device regions may also be useful. The first and second device regions 105 and 205 may or may not be adjacent to each other.

The substrate 101 is prepared with isolation regions 180 for isolating the device regions from other regions. For example, an isolation region surrounds a device region, isolating it from other device regions. The isolation regions 180, for example, are STI regions. Other types of isolation regions may also be useful. Various processes can be employed to form the STI regions. For example, the substrate can be etched using etch and mask techniques to form trenches which are then filled with dielectric materials such as silicon oxide. Chemical mechanical polishing (CMP) can be performed to remove excess oxide and provide a planar substrate top surface. Other processes or materials can also be used to form the STIs. The depth of the STI regions may be, for example, about 2000-5000 Å. Other suitable depth dimensions for the STI regions may also be useful.

The substrate 101 is prepared with device wells 112 in the first and second device regions 105 and 205. The device wells 112 may be formed by ion implantation. To form the device wells, an implant mask (not shown) which exposes the device regions is used. The implant mask, for example, is a photoresist layer patterned by a lithographic mask. The implant, for example, includes implanting second polarity type dopants into the substrate.

In one embodiment, the device wells 112 are doped with second polarity type dopants. For example, the device wells are doped with p-type dopants. Alternatively, the second polarity type dopants may be n-type. The device wells serve as bodies of transistors. A depth of the device wells may be about 0.5-5 μm. Other suitable depth dimensions for the device wells may also be useful. The dopant concentration of the device wells may be light to intermediate. For example, the dopant concentration of the device wells may be about 5E12-5E13/cm². Other suitable dopant concentration for the device well may also be useful.

Referring to FIG. 2b, gate layers of the gates are formed on the substrate. In one embodiment, the gate layers include a gate dielectric layer 234 on the substrate 101 and a gate electrode layer 236 formed thereon.

In one embodiment, the gate dielectric layer 234 is silicon oxide. Other suitable types of gate dielectric, for example, high k gate dielectric, may also be useful. The thickness of the gate dielectric layer 234 depends on the thickness of gate dielectric required for the medium voltage I/O transistor. In one embodiment, the gate dielectric layer of the switch transistor in the first device region 105 is formed simultaneously with the gate dielectric layer of the medium voltage I/O transistor in the second device region 205. The thickness of the gate dielectric layer 234, for example, may be about 50-200 Å. Other suitable thickness dimensions may also be useful. The gate dielectric layer may be formed by thermal oxidation. For example, the dielectric layer is formed by wet oxidation followed by annealing the substrate in an oxidizing ambient. The temperature of the wet oxidation can be, for example, about 600-1000° C. Forming other types of gate dielectric layers or using other processes may also be useful.

As shown, the thickness of the gate dielectrics for the transistors is the same. For example, the second transistor which will be formed in the second device region 205 is a medium voltage I/O transistor and the first or switch transistor which will be formed in the first device region 105 will have the same thickness as the gate dielectric of the second or medium voltage I/O transistor.

As for the gate electrode layer 236, it may be a silicon layer. The silicon layer for example, may be a polysilicon layer. The thickness of the gate electrode layer may be about 1000-5000 Å. Other suitable thickness dimensions may also be useful. The gate electrode layer may be formed by, for example, chemical vapor deposition (CVD). Other techniques for forming the gate electrode layer may also be useful. The gate electrode layer 236 can be formed as an amorphous or non-amorphous layer. In the case of an amorphous layer, an anneal may be performed to form a polycrystalline silicon layer.

Other types of gate dielectric 234 and gate electrode 236 materials or thicknesses may also be useful. For example, the gate dielectric material may be a high k dielectric material while the gate electrode may be a metal gate electrode material. Other configuration of gate layers may also be useful. For example, the gate dielectric and/or gate electrode layers may have multiple layers. The layers can be formed by various techniques, such as thermal oxidation, CVD and sputtering.

In FIG. 2c, the gate layers are patterned to form first and second gates 125 and 225 of the first and second transistors. An etch mask may be employed to pattern the gate layers to form the gates. For example, a soft mask, such as a photoresist layer, may be used. An exposure source may selectively expose the photoresist layer through a reticle containing the desired pattern. After selectively exposing the photoresist layer, it is developed to form openings corresponding to locations where the gate layers are to be removed. To improve lithographic resolution, an anti-reflective coating (ARC) may be used below the photoresist layer.

In other embodiments, the mask layer may be a hard mask layer. The hard mask layer, for example, may include tetraethyl orthosilicate (TEOS) or silicon nitride. Other types of hard mask materials may also be used. The hard mask layer may be patterned using a soft mask, such as a photoresist.

An anisotropic etch, such as reactive ion etch (RIE) is performed using the etch mask to pattern the gate layers to form the gates. Other types of etch processes may also be useful. In one embodiment, a RIE is employed to pattern the gate layers to form the gates 125 and 225. The gates, for example, may be gate conductors which serve as common gates for multiple transistors. Other configurations of the gate may also be useful.

Referring to FIG. 2d, a mask 284 is formed on the substrate 101. The mask, for example, is a photoresist mask. Other types of mask may also be useful. The mask 284 is patterned to form openings in the first and second device regions 105 and 205 while protecting a portion of the first device region 105. The mask 284 protects a portion of the first device region 105 from subsequent processing.

An ion implantation is performed. As shown, the mask serves as an implant mask, protecting a portion of the first device region 105 from the implant. In one embodiment, an implant is performed to form second type doped regions. The second type doped regions, for example, include first LDD regions 154 in the first and second device regions and a second LDD region 224 in only the second device region 205. For example, the first device region 105 is devoid of a second LDD region 224. The implant, for example, is a high tilt angled implant. Other angled implants may also be useful. First polarity type dopants are implanted into the substrate to form the LDD regions in the first and second device regions.

The implant, for example, serves to form LDD regions 154 and 224 in the exposed substrate portions between the gate and isolation region in the first and second device regions 105 and 205. For example, the implant may dope the substrate exposed by the implant mask between the first and second gates 125 and 225 and isolation regions 180. The depth of the LDD regions 154 and 224, for example, may be about 0.05-0.3 μm. The implant dose may be about 1E13-1E14/cm² and the implant energy may be about 0.1-200 KeV. Other suitable implant parameters may also be useful. In one embodiment, the implant is angled to form LDD regions which underlap a portion of the first and second gates 125 and 225. For example, the implant is performed at about 20-45 degree with reference to the surface of the substrate. The LDD regions, for example, underlap the gates by about 0.1-0.3 μm. Providing LDD regions which extend under the gates by other distances may also be useful.

The LDD regions of the first and second device regions 105 and 205, as described, are formed by the same implant. Forming the LDD regions by separate implant processes may also be useful. After the LDD regions are formed, the implant mask is removed. The implant mask may be removed by, for example, ashing. Other techniques for removing the implant mask may also be useful. An anneal, such as rapid thermal anneal (RTA), is performed after the implant to activate the dopants in the LDD regions.

As shown in FIG. 2e, sidewall spacers 138 are formed on the sidewalls of the gates. To form the sidewall spacers, a dielectric layer is deposited on the substrate. The dielectric layer, for example, may be silicon oxide. Other types of dielectric material, such as silicon nitride, may also be used. The dielectric layer may be formed by CVD. The dielectric layer may also be formed using other techniques. The thickness for the dielectric layer may be, for example, 100-1000 Å. Other thickness for the dielectric layer may also be useful. The thickness, for example, may depend on the desired width of the spacers. An anisotropic etch, such as RIE, may be performed to remove horizontal portions of the dielectric layer, leaving spacers on the sidewalls of the gate. In some applications, the spacers may be formed from multiple dielectric layers.

First and second first type doped regions 120 and 150 are formed in the substrate adjacent to the first and second gates. The first type doped regions are heavily doped regions having first polarity type dopants. An implant, for example, is performed using an implant mask (not shown), such as a photoresist mask, to form the first and second first type doped regions 120 and 150 in the first and second device regions 105 and 205. For example, the implant may dope the substrate exposed by the implant mask between the gate with the spacers and the isolation regions. The implant forms first and second heavily doped regions 120 and 150 which have inner edges 120a and 150a that are aligned with about the first and second sidewalls 125a-125b and 225a-225b of the first and second gates. The depth of the heavily doped regions, for example, is about 0.1-0.4 μm. Providing doped regions having other depths may also be useful. The implant dose may be about 1E15-1E17/cm² and the implant energy may be about 10-100 KeV. Other suitable implant parameters may also be useful. The first doped regions 120 serve as the source regions while the second doped regions 150 serve as the drain regions of the first and second transistors 110 and 210. An anneal, such as RTA, is performed after the implant to activate the dopants in the source and drain regions. The inner edges of the heavily doped regions, for example, may extend under the dielectric spacers due to diffusion of the dopants from the first type doped regions. The first and second first type doped regions, as described, are formed by the same implant. Forming the first type doped regions by separate implant processes may also be useful.

As shown, the first device region 105 includes an asymmetrical switch transistor 110 while the second device region 205 includes a symmetrical medium voltage I/O transistor 210 disposed on the same substrate. After forming the source/drain (S/D) regions, the implant mask is removed. The implant mask may be removed by, for example, ashing. Other techniques for removing the implant mask may also be useful.

Referring to FIG. 2f, metal silicide contacts are formed on contact regions of the first and second transistors 110 and 210. For example, the metal silicide contacts 172 and 173 are formed on the gates and S/D regions of the transistors. The metal silicide contacts, for example, are nickel based metal silicide contacts. Other types of metal silicide contacts may also be useful. The metal silicide contacts are used to facilitate low resistance contacts between the active substrate and the BEOL metal lines. In one embodiment, the thickness of the salicide contacts is about 50-300 Å. Providing other thickness may also be useful.

To form the silicide contacts, a metal layer is deposited on the surface of the substrate. The metal layer, for example, may be nickel or an alloy thereof. Other types of metallic layers, such as cobalt, or alloys thereof, including nickel, may also be used. The metal layer can be formed by Physical Vapor Deposition (PVD). Other types of metal layers and/or other types of forming processes may also be useful.

An anneal may be performed to cause a reaction between the metal and the substrate, forming a silicide layer. Excess metal not reacted in the silicidation of the active surface is removed by, for example, a wet removal process. For example, unreacted metal material is removed selective to the silicide contacts. Other techniques for forming the silicide contacts may also be useful.

The process continues to form the device. The processing may include forming a PMD layer and contacts to the terminals of the devices as well as one or more interconnect levels, final passivation, dicing, assembly and packaging. Other processes may also be included. For example, other components, such as high voltage devices, low voltage logic devices, memory devices or other types of devices can be formed prior to forming the interconnections.

The device formed by the process as described in FIGS. 2a-2f, for example, include all advantages as described with respect to FIG. 1. As such, these advantages will not be described or described in detail. As described, in one embodiment, the switch transistor can be formed together or simultaneously with I/O devices without requiring additional or extra mask compared with baseline processes. As such, no extra cost is incurred to incorporate the switch transistor on the same substrate.

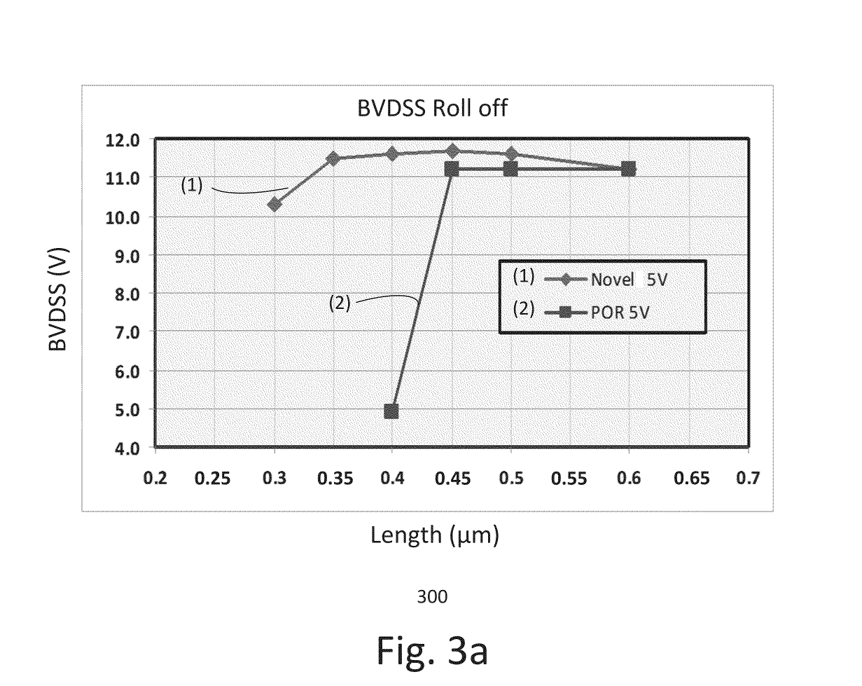

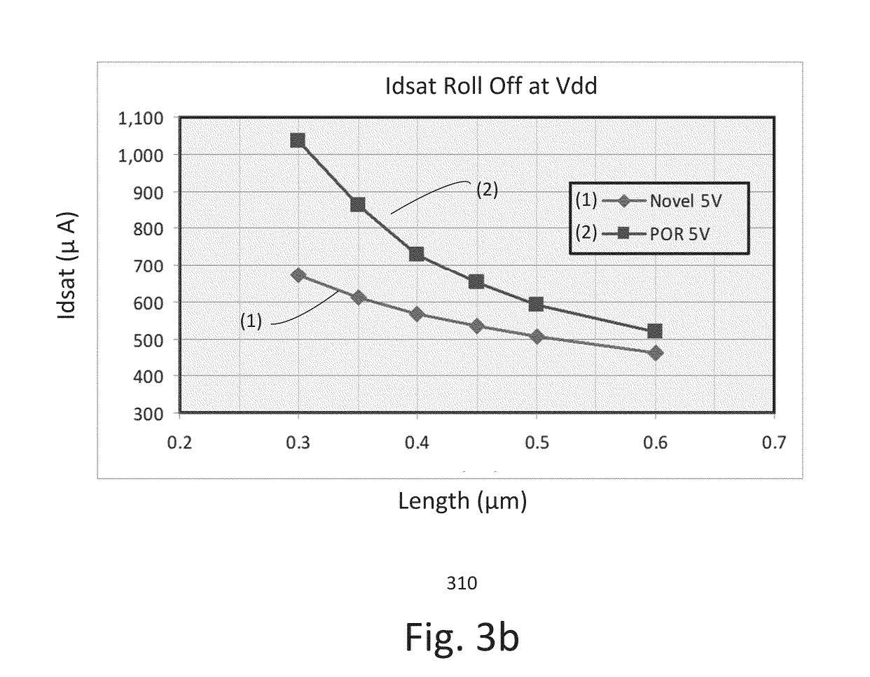

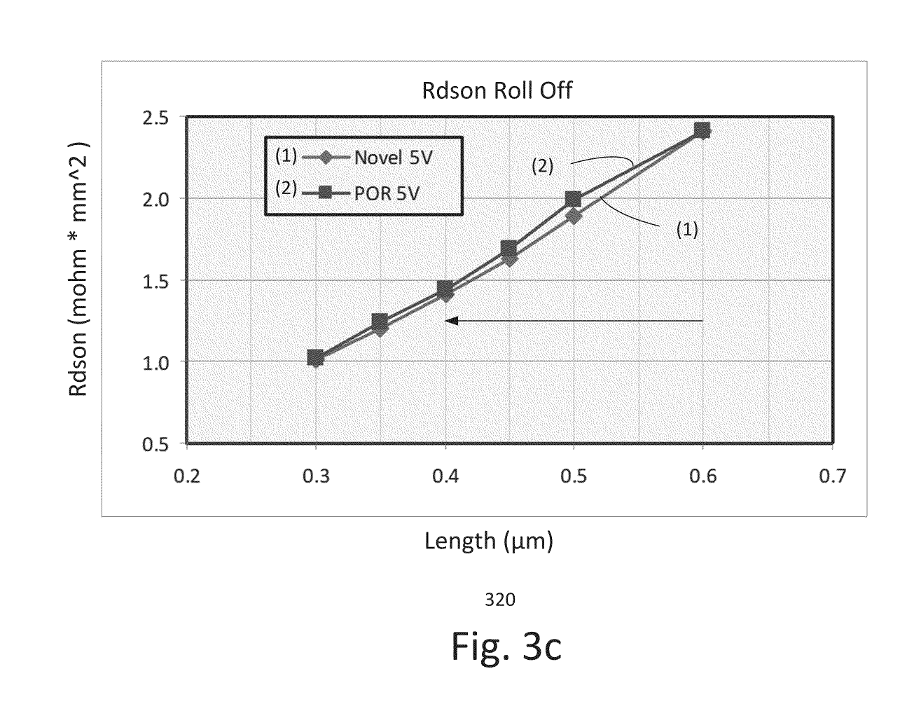

FIGS. 3a-3c show graphs charting exemplary performance data of the switch transistor in accordance with the embodiment as described in FIG. 1 and a conventional switch transistor. In the graphs, line 1 represents the switch transistor having only a LDD region adjacent to the drain in accordance to the present disclosure and line 2 represents the conventional switch transistor having LDD regions adjacent to both source and drain regions.

FIG. 3a shows a graph plotting drain-to-source breakdown voltage (BVDSS) with respect to channel length (L) when the drain leakage current reaches 0.1 μA/μm. As shown, the BVDSS for line 2 drops exponentially when the L reaches about 0.45 μm. On the other hand, the BVDSS for line 1 drops significantly when the L reaches 0.35 μm. In other words, the conventional switch transistor having LDD regions adjacent to both source and drain regions cannot be scaled down further after its channel length reaches about 0.45 μm. On the other hand, by forming LDD region only adjacent to the drain region allows the channel length of the switch transistor to be further reduced by 0.1 μm while maintaining its breakdown voltage. A reduced channel length, for example, allows smaller transistor to be formed. This can also lower the R_{DSon} without affecting the drain electric field distribution.

FIG. 3b shows a graph plotting drain saturation current (Idsat) relative to channel length (L) at drain voltage (Vd) of about 5V. As shown in FIG. 3b, Idsat for line 2 increased exponentially or experienced roll-up when the channel length of the conventional switch transistor is reduced to less than 0.45 μm. As such, short channel effect becomes especially pronounced when the channel length of the conventional switch transistor is reduced to less than 0.45 μm. On the other hand, Idsat of line 1 increases minimally or the Idsat roll off is not significant even when the channel length of the switch transistor as described in FIG. 1 is reduced from 0.45 μm to 0.35 μm. Thus, short channel effect is not observed even when the channel length of the switch transistor as described in FIG. 1 is reduced to be lower than 0.45 μm.

FIG. 3c shows a graph plotting drain-to-source on resistance (R_{DSon}) with respect to the channel length (L) at Vd of about 5 V. As shown, line 1 shows slightly lower R_{DSon} than line 2 across different channel lengths. Considering the reliability concern such as hot carrier injection (HCI), line 2 which represents the conventional switch transistor having LDD regions adjacent to both source and drain regions is limited to the minimum channel length of 0.6 μm with R_{DSon} of about 2.5 mohm*mm². On the other hand, line 1 which represents the switch transistor having only a LDD region adjacent to the drain in accordance to the present disclosure can use the minimum channel length of 0.4 μm with R_{DSon} of about 1.5 mohm*mm². The reduction of R_{DSon} of line 1 compared with line 2 is about 40%. Thus, the switch transistor having only a LDD region adjacent to the drain in accordance to the present disclosure clearly exhibits significant reduction of R_{DSon} relative to conventional switch transistor having LDD regions adjacent to both source and drain regions. This is advantageous as lower R_{DSon} leads to higher switching speed and less power loss during switching operations.

The invention may be embodied in other specific forms without departing from the spirit or essential characteristics thereof. The foregoing embodiments, therefore, are to be considered in all respects illustrative rather than limiting the invention described herein. Scope of the invention is thus indicated by the appended claims, rather than by the foregoing description, and all changes that come within the meaning and range of equivalency of the claims are intended to be embraced therein.

What is claimed is:

1. A device comprising:
a substrate having a device region for a switch transistor;
a switch transistor having a gate disposed on the substrate in the device region; and
first and second heavily doped regions disposed adjacent to the gate, wherein the first heavily doped region serves as a source region of the switch transistor and the second heavily doped region serves as a drain region of the switch transistor, wherein the drain region includes a lightly doped diffusion (LDD) region adjacent thereto and the source region is devoid of a LDD region.

2. The device of claim 1 comprising:
a device well having second polarity type dopants disposed in the substrate, and wherein
the heavily doped regions and the LDD region comprise first polarity type dopants, wherein the first and second polarity type dopants are different.

3. The device of claim 1 wherein the LDD region which is adjacent to the drain region underlaps a portion of the gate.

4. The device of claim 1 wherein:
the substrate further includes an input/output (I/O) device region for an I/O transistor; and comprising
a gate disposed on the substrate in the I/O device region.

5. The device of claim 4 wherein:
the gate of the I/O transistor and the gate of the switch transistor comprise gate dielectric and gate electrode layers, and wherein the gate dielectric layers of the I/O transistor and switch transistor comprise the same thickness.

6. A method of forming a device comprising:
providing a substrate having a first device region for a switch transistor;
forming a switch transistor having a gate on the substrate in the first device region;
forming first and second heavily doped regions adjacent to the gate, wherein the first heavily doped region serves as a source region of the switch transistor and the second heavily doped region serves as a drain region of the switch transistor, wherein the drain region includes a lightly doped diffusion (LDD) region adjacent thereto and the source region is devoid of a LDD region.

7. The method of claim 6 comprising forming sidewall spacers on first and second sidewalls of the gate, wherein the first and second heavily doped regions are aligned with about inner edges of the sidewall spacers.

8. The method of claim 6 wherein:
the substrate includes a second device region for an input/output (I/O) transistor; and comprising
forming an I/O transistor having a gate, wherein the gate comprises sidewall spacers on first and second sidewalls of the gate in the second device region on the substrate.

9. The method of claim 8 comprising:
providing a mask having openings exposing the first and second device regions while covering a portion of the first device region on the substrate; and
performing an implant to form LDD regions adjacent to the first and second sidewalls of the gate in the second device region and to form the LDD region adjacent to the second sidewall of the gate in the first device region.

10. The method of claim 8 wherein the gates of the switch and I/O transistors comprise gate dielectric layers and gate electrodes.

11. The method of claim 10 wherein the gate dielectric layers of the switch and I/O transistors comprise the same thickness.

12. A method of forming a device comprising:
providing a substrate having at least a first device region for a first transistor and a second device region for a second transistor;
forming a first gate having first and second sidewalls on the first device region and a second gate having first and second sidewalls on the second device region, wherein the gates include sidewall spacers on their sidewalls;
forming heavily doped regions adjacent to the gates, wherein inner edges of the heavily doped regions are aligned with about inner edges of the sidewall spacers of the gates, the heavily doped regions serve as source/drain (S/D) regions of the gates, wherein the source region of the first transistor does not include lightly doped diffusion (LDD) region.

13. The method of claim 12 wherein the first transistor comprises a switch transistor and the second transistor comprises an input/output (I/O) transistor.

14. The method of claim 13 wherein the I/O transistor is a medium voltage I/O transistor.

15. The method of claim 13 wherein forming the first gate and the second gate comprises:
forming a gate dielectric layer on a top surface of the substrate and a gate electrode layer over the gate dielectric layer; and
patterning the gate dielectric and gate electrode layers to form the first and second gates.

16. The method of claim 15 wherein the gate dielectrics of the first and second gate comprise the same thickness.

17. The method of claim 12 comprising:
providing a mask having openings exposing the first and second device regions while covering a portion of the first device region on the substrate; and
performing an implant to form LDD regions adjacent to the first and second sidewalls of the second gate in the second device region and to form the LDD region adjacent to the second sidewall of the first gate in the first device region.

18. The method of claim 17 wherein the implant to form the LDD regions comprises an angled implant and the LDD regions extend under a portion of the first and second gates.

19. The method of claim 17 comprising:
forming a device well having second polarity type dopants in the substrate, and wherein
the heavily doped regions and the LDD regions comprise first polarity type dopants, wherein the first and second polarity type dopants are different.

20. The method of claim 12 wherein the heavily doped regions comprise a depth which is deeper than a depth of the LDD region relative from a top surface of the substrate.
